(19) United States
(12) Patent Application Publication
(10) Pub. No.: US 2026/0074699 A1
(43) Pub. Date: Mar. 12, 2026

(54) LEVEL SHIFTING LATCH CIRCUIT

(71) Applicant: APPLE INC., CUPERTINO, CA (US)

(72) Inventors: VIVEKANANDAN VENUGOPAL, SARATOGA, CA (US); RAJIV MITTAL, SANTA CLARA, CA (US); SAHIL KAPOOR, SUNNYVALE, CA (US); CHANDAN SHANTHARAJ, SAN JOSE, CA (US)

(21) Appl. No.: 18/987,863

(22) Filed: Dec. 19, 2024

Related U.S. Application Data
(60) Provisional application No. 63/692,159, filed on Sep. 8, 2024.

(51) Int. Cl. H03K 19/0185; H03K 3/356

(52) U.S. Cl. CPC H03K 19/018521; H03K 3/356113

(57) ABSTRACT

An apparatus according to an example includes a first circuit configured to receive an input signal from a first voltage domain and perform level shifting and latching functions on the input signal. The apparatus includes a second circuit coupled to the first circuit and configured to receive the input signal from the first voltage domain at an input of the second circuit, perform level shifting on the input signal, and provide a level-shifted signal for a second voltage domain at an output of the second circuit.

### CROSS REFERENCE TO RELATED APPLICATION

This application is a non-provisional utility application for patent entitled to a filing date and claiming the benefit of earlier-filed U.S. Provisional Ser. No. 63/692,159, filed Sep. 8, 2024, which is hereby incorporated herein by reference in its entirety.

### BACKGROUND

### Technical Field

Embodiments described herein are related to the field of integrated circuit implementation, and more particularly to level shifting latch circuits.

### Description of the Related Art

Integrated circuits (ICs), such as, for example, systems-on-chip (SoCs), may include more than one power supply for supplying power to various circuits in a given SoC. Some power supplies may output a power signal at a different voltage level from other power supplies. In some SoCs, one or more voltage regulators may be used to generate power signals of varying voltage levels from a given power supply. These various power signals may be used by different circuits in an SoC, each power signal supplying power in what may be referred to as a respective “power domain” or “voltage domain. ” Circuits being powered by a common power signal may be considered to be in the same power domain. In an example SoC, a processing core may be in a first power domain and a memory may be in a second power domain. Data and control signals used between the core and the memory may need to be shifted from the first power domain to the second power domain, and vice versa, through the use of level shifting circuits.

### SUMMARY OF VARIOUS EMBODIMENTS

Various embodiments of a level shifting latch circuit are disclosed. The level shifting latch circuit may perform both level shifting and latching functions. The level shifting latch circuit may include a latch portion/path that may perform level shifting and latch functions, and a bypass portion/path that may also perform level shifting and allow signals/data to flow through the level shifting latch circuit in two stages.

Some examples of the level shifting latch circuit may include a bypass portion/path to bypass latching and go from the input to the output. In some examples, the latch function as well as the level shifting function performed by the latch portion/path happen concurrently (e.g., simultaneously) with the operation of the bypass path without impacting the bypass path. In some examples, the bypass portion/path and the latch portion/path concurrently operate on the input signal.

An example of the present disclosure is directed to an apparatus, which includes a first circuit configured to receive an input signal from a first voltage domain and perform level shifting and latching functions on the input signal. The apparatus includes a second circuit coupled to the first circuit and configured to receive the input signal from the first voltage domain at an input of the second circuit, perform level shifting on the input signal, and provide a level-shifted signal for a second voltage domain at an output of the second circuit.

### BRIEF DESCRIPTION OF THE DRAWINGS

The following detailed description makes reference to the accompanying drawings, which are now briefly described.

FIG. 1 illustrates a block diagram of an example SoC, in accordance with one or more embodiments of the present disclosure.

FIG. 2 illustrates a block diagram of an example SoC, in accordance with further embodiments of the present disclosure.

FIG. 3 illustrates a diagram of an example level shifting latch circuit, in accordance with one or more embodiments of the present disclosure.

FIG. 4 illustrates a block diagram of an example computer system, in accordance with one or more embodiments of the present disclosure.

While the disclosure is susceptible to various modifications and alternative forms, specific embodiments thereof are shown by way of example in the drawings and will herein be described in detail. It should be understood, however, that the drawings and detailed description thereto are not intended to limit the disclosure to the particular form illustrated, but on the contrary, the intention is to cover all modifications, equivalents and alternatives falling within the spirit and scope of the present disclosure as defined by the appended claims. The headings used herein are for organizational purposes only and are not meant to be used to limit the scope of the description. As used throughout this application, the word “may” is used in a permissive sense (i.e., meaning having the potential to), rather than the mandatory sense (i.e., meaning must). Similarly, the words “include,” “including,” and “includes” mean including, but not limited to.

### DETAILED DESCRIPTION OF EMBODIMENTS

Systems-on-chip (SoCs) may include multiple circuits operating at different power supply levels. A voltage level of each power signal may be different from the other power supplies. As referred to herein, a “power domain” or a “voltage domain” refers to a group of circuits coupled to a common power signal. When a logic signal is transmitted from a first voltage domain into a second voltage domain, the signal may need to be level shifted to a voltage level that is compatible with the second voltage domain, and vice versa when transmitting a signal from the second voltage domain to the first voltage domain. For example, a first circuit may be in a 1.2V voltage domain, meaning logic signals transition between approximately 1.2V and 0V to indicate logic high and logic low levels, respectively. A second circuit may be in a 0.8V voltage domain. A logic level from the 1.2V domain may be too high of a voltage level for the 0.8V domain, and could possibly damage circuits. Conversely, a logic high level from the 0.8V domain may be too low to be detected as a logic high in the 1.2V domain. In addition, voltage level mismatches between voltage domains may cause leakage or other performance issues due to transistors not being turned on completely by the mismatched voltage level. Level shifting circuits may be used to transmit logic signals between voltage domains and mitigate these types of issues.

In some computing systems, there may be a critical path that involves latching and level shifting in the data path, such as a central processing unit's (CPU's) fundamental timing critical path dictating Fmax (the maximum clock frequency at which the CPU can operate). The latch may be used for hold protection (e.g., to hold the state of the memory) to handle a large separation between VDDI and VDDO, such as when one of the power supply voltages (e.g., VDDO) is in a low state and the other power supply voltage (e.g., VDDI) is in a higher state.

However, the latch may add timing pressure when VDDI and VDDO are both high, so it is helpful to reduce the delay of the latching and level shifting. Some designs may use three separate high performance cells (e.g., a latch cell, an inverter, and a level shifter cell) to attempt to achieve the timing requirement. The latch may have three stages, and the level shifter may have two or three stages, so that there may be five or more stages to go from input D to output Q. Some examples disclosed herein replace the three cells with a single level shifting latch circuit with a timing critical path that has two stages for data propagation from input D to output Q to achieve a higher Fmax.

Embodiments of systems, apparatuses, and methods for shifting voltage levels of a logic signal are disclosed herein. The disclosed embodiments demonstrate methods for shifting a voltage level of a logic signal travelling between two different voltage domains. Moreover, these embodiments disclose level shifting circuits that may be capable of shifting voltage levels between voltage domains with wide differences between respective voltage levels.

An example of the present disclosure is directed to an apparatus. The apparatus includes a first circuit configured to receive an input signal from a first voltage domain and perform level shifting and latching functions on the input signal. The apparatus includes a second circuit coupled to the first circuit and configured to receive the input signal from the first voltage domain at an input of the second circuit, perform level shifting on the input signal, and provide a level-shifted signal for a second voltage domain at an output of the second circuit.

In some examples of the apparatus, the first circuit and the second circuit operate concurrently on the input signal. In some examples of the apparatus, the latching performed by the first circuit provides hold protection for the input signal.

In some examples of the apparatus, the second circuit is configured to provide the level-shifted signal to the output in two stages. In some examples, the input signal is a falling signal, wherein a first stage of the two stages includes inverting the input signal to generate an inverted signal, and wherein a second stage of the two stages includes turning on a first transistor, coupled to the output, with the inverted signal to cause a level-shifted falling signal to be transferred to the output. In some examples, the input signal is a rising signal, wherein a first stage of the two stages includes turning on a second transistor, coupled to a gate of a third transistor that is coupled to the output, with the input signal, and wherein a second stage of the two stages includes turning on the third transistor to cause a level-shifted rising signal to be transferred to the output.

In some examples of the apparatus, the first voltage domain is a memory voltage domain and the second voltage domain is a processor voltage domain.

Another example of the present disclosure is directed to a level shifting latch circuit, which includes a latch portion comprising a cross-coupled field-effect transistor (FET) structure for level shifting an input signal from a first domain to a second domain and a second FET structure for latching the input signal. The level shifting latch circuit includes a bypass portion comprising a first set of two stages for level shifting and outputting the input signal when the input signal is a falling signal, and a second set of two stages for level shifting and outputting the input signal when the input signal is a rising signal.

In some examples of the level shifting latch circuit, the cross-coupled FET structure includes a first FET and a second FET coupled in series between a power supply node and a second node; and a third FET and a fourth FET coupled in series between the power supply node and a third node, wherein a gate of the first FET and the fourth FET are coupled together and coupled to the third node, and wherein a gate of the second FET and the third FET are coupled together and coupled to the second node. In some examples, the first FET, the second FET, the third FET, and the fourth FET are each a p-channel metal-oxide-semiconductor field-effect transistor (PMOS FET).

In some examples of the level shifting latch circuit, the second FET structure comprises a fifth FET and a sixth FET coupled in series between the second node and ground, and a seventh FET and an eighth FET coupled in series between the third node and ground. In some examples, the fifth FET, the sixth FET, the seventh FET, and the eighth FET are each an n-channel metal-oxide-semiconductor field-effect transistor (NMOS FET). In some examples, the bypass portion is coupled to the latch portion at a node between the third FET and the fourth FET.

In some examples of the level shifting latch circuit, a first stage of the first set of two stages includes an inverter for inverting the falling signal to generate an inverted signal, and wherein a second stage of the first set of two stages includes a first FET coupled an output of the bypass portion, wherein the first FET is turned on with the inverted signal to cause a level-shifted falling signal to be transferred to the output. In some examples of the level shifting latch circuit, a first stage of the second set of two stages includes a second FET that is turned on with the input signal, wherein a second stage of the second set of two stages includes a third FET, wherein the second FET is coupled to a gate of the third FET, wherein the third FET is coupled to an output of the bypass portion, and wherein turning on the third FET with the second FET causes a level-shifted rising signal to be transferred to the output. In some examples, the second FET is an n-channel metal-oxide-semiconductor field-effect transistor (NMOS FET), and wherein the third FET is a p-channel metal-oxide-semiconductor field-effect transistor (PMOS FET).

Another example of the present disclosure is directed to a method. The method includes receiving, by a first circuit from a first voltage domain, an input signal. The method includes performing, by the first circuit, level shifting and latching functions on the input signal. The method includes receiving, by a second circuit coupled to the first circuit, the input signal from the first voltage domain at an input of the second circuit. The method includes performing, by the second circuit, level shifting on the input signal. The method includes providing, by the second circuit, a level-shifted signal for a second voltage domain at an output of the second circuit.

In some examples of the method, the first circuit and the second circuit operate concurrently on the input signal. In some examples of the method, the latching performed by the first circuit provides hold protection for the input signal. In some examples of the method, the second circuit is configured to provide the level-shifted signal to the output in two stages.

Many terms commonly used in reference to SoC designs are used in this disclosure. For the sake of clarity, the intended definitions of some of these terms, unless stated otherwise, are as follows.

A Metal-Oxide Semiconductor Field-Effect Transistor (MOSFET) describes a type of transistor that may be used in modern digital logic designs. MOSFETs are designed as one of two basic types, n-channel and p-channel. N-channel MOSFETs open a conductive path between the source and drain when a positive voltage greater than the transistor's threshold voltage is applied between the gate and the source. P-channel MOSFETs open a conductive path when a voltage greater than the transistor's threshold voltage is applied between the drain and the gate.

Complementary MOSFET (CMOS) describes a circuit designed with a mix of n-channel and p-channel MOSFETs. In CMOS designs, n-channel and p-channel MOSFETs may be arranged such that a high level on the gate of a MOSFET turns an n-channel transistor on, i.e., opens a conductive path, and turns a p-channel MOSFET off, i.e., closes a conductive path. Conversely, a low level on the gate of a MOSFET turns a p-channel on and an n-channel off. In addition, the term transconductance is used in parts of the disclosure. While CMOS logic is used in the examples, it is noted that any suitable digital logic process may be used for the circuits described in this disclosure.

It is noted that “high,” “high level,” and “high logic level” refer to a voltage sufficiently large to turn on a n-channel MOSFET and turn off a p-channel MOSFET while “low,” “low level,” and “low logic level” refer to a voltage that is sufficiently small enough to do the opposite. As used herein, a “logic signal” refers to a signal that transitions between a high logic level and a low logic level. In various other embodiments, different technology may result in different voltage levels for “low” and “high. ”

The embodiments illustrated and described herein may employ CMOS circuits. In various other embodiments, however, other suitable technologies may be employed.

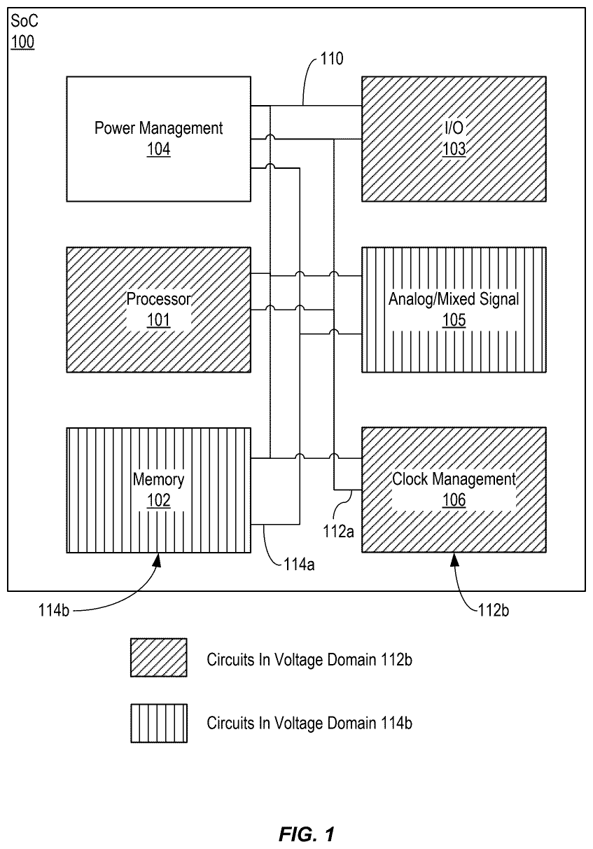

FIG. 1 illustrates a block diagram of an example SoC 100, in accordance with one or more embodiments of the present disclosure. SoC 100 includes processor 101 coupled to Memory Block 102, I/O block 103, Power Management Unit 104, Analog/Mixed-Signal Block 105, Clock Management Unit 106, all coupled through Bus 110. Additionally, Power Management Unit 104 may provide a Power Signal 112a to a first set of the circuit blocks in SoC 100 and Power Signal 114a to a second set of the circuit blocks. In various embodiments, SoC 100 may be configured for use in a mobile computing application such as, e.g., a tablet computer, smartphone or wearable device.

Processor 101 may, in various embodiments, be representative of a general-purpose processor that performs computational operations. For example, Processor 101 may be a central processing unit (CPU) such as a microprocessor, a microcontroller, an application-specific integrated circuit (ASIC), or a field-programmable gate array (FPGA). In some embodiments, Processor 101 may include multiple CPU cores and may include one or more register files and memories. In various embodiments, Processor 101 may implement any suitable instruction set architecture (ISA), such as, e.g., PowerPC™, ARM®, or x86 ISAs, or combination thereof.

Memory Block 102 may include any suitable type of memory such as, for example, a Dynamic Random Access Memory (DRAM), a Static Random Access Memory (SRAM), a Read-only Memory (ROM), Electrically Erasable Programmable Read-only Memory (EEPROM), a FLASH memory, a Ferroelectric Random Access Memory (FeRAM), Resistive Random Access Memory (RRAM or ReRAM), or a Magnetoresistive Random Access Memory (MRAM). Some embodiments may include a single memory, such as Memory Block 102 and other embodiments may include more than two memory blocks (not shown). Memory Block 102, may, in some embodiments, include a memory controller for interfacing to memory external to SoC 100, such as, for example, one or more DRAM chips.

I/O Block 103 may be configured to coordinate data transfer between SoC 100 and one or more peripheral devices. Such peripheral devices may include, without limitation, storage devices (e.g., magnetic or optical media-based storage devices including hard drives, tape drives, CD drives, DVD drives, etc.), audio processing subsystems, graphics processing subsystems, or any other suitable type of peripheral devices. I/O Block 103 may include general-purpose input/output pins (I/O pins). In some embodiments, I/O Block 103 may be configured to implement a version of Universal Serial Bus (USB) protocol, IEEE 1394 (Firewire) protocol, or Ethernet (IEEE 802.3) networking protocol.

Power Management Unit 104 may be configured to manage power delivery to some or all of the circuit blocks included in SoC 100. Power Management Unit 104 may include sub-blocks for managing multiple power supplies for various circuit blocks. In various embodiments, the power supplies may be located in Analog/Mixed-Signal Block 105, in Power Management Unit 104, in other blocks within SoC 100, or come from a source external to SoC 100 and coupled through power supply pins. Power Management Unit 104 may include one or more voltage regulators to adjust outputs of the power supplies to various voltage levels as required by circuit blocks in SoC 100, such as for reduced power modes, for example.

In the illustrated embodiment, Power Management Unit 104 supplies Power Signal 112a to Processor 101, I/O Block 103, and Clock Management Unit 106. These circuit blocks are in Voltage Domain 112b. Power Management Unit 104 supplies Power Signal 114a to Memory Block 102 and Analog/Mixed-Signal Block 105, putting these circuit blocks in Voltage Domain 114b. If a voltage level of Power Signal 112a is different than a voltage level of Power Signal 114a, then logic signals transmitted via System Bus 110 from a circuit block in the Power Signal 112a voltage domain may need to be level shifted before being received by a circuit block in the Power Signal 114a voltage domain.

Analog/Mixed-Signal Block 105 may include a variety of circuits including, for example, a crystal oscillator, an internal oscillator, a phase-locked loop (PLL), delay-locked loop (DLL), or frequency-locked loop (FLL). One or more analog-to-digital converters (ADCs) or digital-to-analog converters (DACs) may also be included in Analog/Mixed-Signal Block 105. In some embodiments, Analog/Mixed-Signal Block 105 may also include radio frequency (RF) circuits that may be configured for operation with cellular telephone networks. Analog/Mixed-Signal Block 105 may include one or more voltage regulators to supply one or more voltages to various circuit blocks and circuits within those blocks.

Clock Management Unit 106 may be configured to enable, configure and monitor outputs of one or more clock sources. In various embodiments, the clock sources may be located in Analog/Mixed-Signal Block 105, within Clock Management Unit 106, in other blocks within SoC 100, or come from external to SoC 100, coupled via one or more I/O pins. Clock Management Unit 106 may include circuits for selecting an output frequency or reference clock of a PLL, FLL, DLL, or other type of closed-loop clock source.

System Bus 110 may be configured as one or more buses to couple Processor 101 to the other circuit blocks within the SoC 100 such as, e.g., Memory Block 102 and I/O Block 103. In some embodiments, System Bus 110 may include interfaces coupled to one or more of the circuit blocks that allow a particular circuit block to communicate through the bus. In some embodiments, System Bus 110 may allow movement of data and transactions (i.e., requests and responses) between circuit blocks without intervention from Processor 101. For example, data received through the I/O Block 103 may be stored directly to Memory Block 102.

It is noted that the SoC illustrated in FIG. 1 is merely an example SoC. In other embodiments, different circuit blocks and different configurations of circuit blocks may be possible dependent upon the specific application for which the SoC is intended.

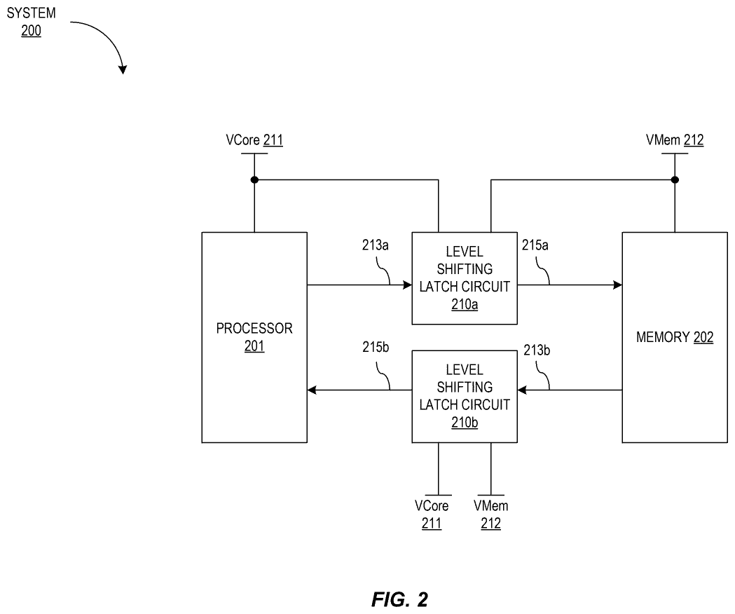

FIG. 2 illustrates a block diagram of an example SoC 200, in accordance with further embodiments of the present disclosure. The SoC 200 includes a processor 201, a memory 202, and level shifting latch circuits 210a and 210b.

Processor 201 is coupled to memory 202 via level shifting latch circuits 210a and 210b. Processor 201 receives power signal VCore 211 and memory 202 receives power signal VMem 212. In some embodiments, processor 201 may correspond to processor 101 in FIG. 1 and memory 202 may correspond to memory block 102. Level shifting latch circuit 210a receives input signal 213a and generates output signal 215a, which may depend on internal signals including an inverted input signal and a power signal. Likewise, level shifting latch circuit 210b receives input signal 213b and generates output signal 215b, which may depend on internal signals including an inverted input signal and a power signal.

In the illustrated embodiment, processor 201 is in the VCore 211 voltage domain and memory 202 is in the VMem 212 voltage domain. In the present embodiment, VMem 212 has a voltage level that is different than that of VCore 211 and, therefore, level shifting latch circuit 210a is used to shift logic signals from processor 201 into the VMem 212 voltage domain and level shifting latch circuit 210b is used to shift signals from memory 202 into the VCore 211 voltage domain.

It is noted that, to improve clarity and to aid in demonstrating the disclosed concepts, the diagram illustrated in FIG. 2 has been simplified. In other embodiments, different and/or additional circuit blocks and different configurations of the circuit blocks are possible and contemplated. The present embodiment uses a processor and a memory as circuit blocks communicating across two voltage domains. In other embodiments, however, any two circuit blocks may communicate across voltage domains.

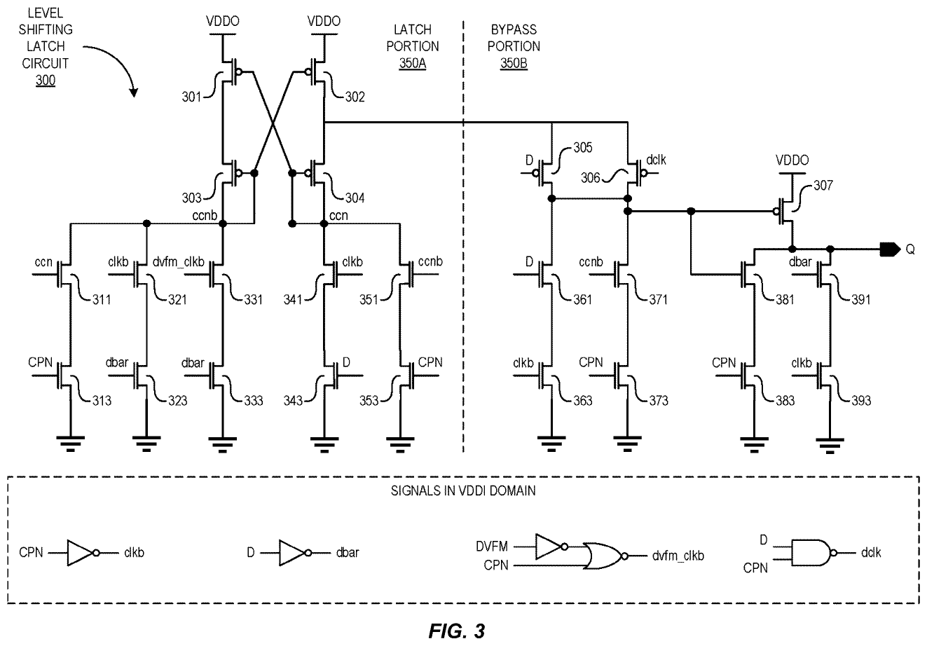

FIG. 3 illustrates a block diagram of an example level shifting latch circuit 300, in accordance with one or more embodiments of the present disclosure. Level shifting latch circuit 300 may be an example of level shifting latch circuit 210a and/or level shifting latch circuit 210b illustrated in FIG. 2. Level shifting latch circuit 300 includes FETS 301 to 307, 311, 313, 321, 323, 331, 333, 341, 343, 351, 353, 361, 363, 371, 373, 381, 383, 391, and 393. FETS 301 to 307 may be p-channel type FETs (e.g., pFETs, PMOS FETS, etc.). FETS 311, 313, 321, 323, 331, 333, 341, 343, 351, 353, 361, 363, 371, 373, 381, 383, 391, and 393 may be n-channel type FETS (e.g., nFETs, NMOS FETS, etc.). Level shifting latch circuit 300 may transmit signals from a first voltage domain VDDI (e.g., an input voltage domain) to a second voltage domain VDDO (e.g., an output voltage domain).

The FETS 301 to 307, 311, 313, 321, 323, 331, 333, 341, 343, 351, 353, 361, 363, 371, 373, 381, 383, 391, and 393 may be controlled by various signals (e.g., voltages, logic levels, etc.). For example, FET 311 is controlled by the ccn signal, FET 313 is controlled by the CPN signal, FET 321 is controlled by the clkb signal, FET 343 is controlled by the D signal, FET 333 is controlled by the dbar signal, FET 306 is controlled by the dclk signal, and FET 331 is controlled by the dvfm_clkb signal.

The CPN signal may be a clock signal received from a clock circuit or other device/circuit that may generate/provide a timing signal. The D signal may be an input to the level shifting latch circuit 300. The level shifting latch circuit 300 may also receive various other signals such as DVFM, ccn, and ccnb. Other signals used to control the FETS 301 to 307, 311, 313, 321, 323, 331, 333, 341, 343, 351, 353, 361, 363, 371, 373, 381, 383, 391, and 393 may be generated based on the DVFM, CPN and D signals.

As illustrated in FIG. 3, the level shifting latch circuit 300 may be divided (logically and/or physically) into two portions, a latch portion 350A and a bypass portion 350B. Latch portion 350A may be referred to as a latch path and bypass portion 350B may be referred to as a bypass path. The FETS in the latch portion 350A may perform level shifting and latching functions. For example, FETS 311 and 313, and FETS 351 and 353 may perform latching functions. In another example, FETS 301 to 304 may perform level shifting functions. In one embodiment, signals and/or data that go through the level shifting latch circuit 300 (from VDDI to VDDO) may pass through both the latch portion 350A and the bypass portion 350B at least partially simultaneously (e.g., in parallel).

In one embodiment, the diode structures created by FETS 303 and 304 may result in FETS 301 and 302, respectively, not requiring as low of a voltage level on their gate terminals to turn on. This easier switching may result in level shifting latch circuit 300 functioning properly even when a voltage difference between VDDI and VDDO is large. As a result, level shifting latch circuit 300 may provide level shifting capabilities across voltage domains with a wide range of respective voltage levels.

As discussed above, signals that go through the level shifting latch circuit 300 may pass through both the latch portion 350A and the bypass portion 350B. Described below are various states of either the latch portion 350A or the bypass portion 350B of the level shifting latch circuit 300 of the example of FIG. 3 based on logical values of various signals.

### State of Bypass Portion of Level Shifting Circuit When CPN Signal ss a Logical Low and D Signal is a Logical Low

In one embodiment, when the signals go through the bypass portion 350B, the CPN signal may be 0 (e.g., logical low) and the D signal may also be 0 (e.g., D may fall or go low). This may occur at a first stage. This may cause signal dbar to be 1 (e.g., logical high) which may turn on FET 391. FET 393 will also be turned on because signal clkb will be 1 when signal CPN is 0. This may allow the D signal (e.g., 0 or logical low) to go to the output Q (at a second stage).

### State of Bypass Portion of Level Shifting Circuit When CPN Signal is a Logical Low and D Signal is a Logical High

In one embodiment, when the signals go through the bypass portion 350B, the CPN signal may be 0 (e.g., logical low) and the D signal may be 1 (e.g., D may rise or go high). This may occur at a first stage. This may turn on FET 361. FET 363 may also be turned on because signal clkb will be 1 when signal CPN is 0. The signals flowing through FETS 361 and 363 may turn on FET 307. This may allow the D signal (e.g., 1 or logical high) to go to the output Q (at a second stage).

### State of Latch Portion of Level Shifting Circuit When CPN Signal is a Logical Low and D Signal is a Logical Low

In one embodiment when the signals go through the latch portion 350A, the CPN signal may be 0 (e.g., logical low) and the D signal may also be 0 (e.g., D may fall or go low). This may turn off FET 313. This may also turn on FETS 321 and 323 because signal clkb will be 1 when signal CPN is 0 and dbar will be 1 when D is 0. In addition, FET 301 will be turned off and FET 302 will be turned on. This allows a logical high signal to be provided to FET 305. FET 305 is turned on because the D signal is 0. FET 306 is turned off because when D is 0 and CPN is 0, the dclk signal will be 1. The logical high signal may go through FET 305 to FET 307, which turns off FET 307. The signal dbar may be 1 (e.g., logical high) because the D signal is 0, which may turn on FET 391. FET 393 will also be turned on because signal clkb will be 1 when signal CPN is 0. This may allow the D signal (e.g., 0 or logical low) to go to the output Q (at a second stage).

### State of Latch Portion of Level Shifting Circuit When CPN Signal is a Logical Low and D Signal is a Logical High

In one embodiment when the signals go through the latch portion 350A, the CPN signal may be 0 (e.g., logical low) and the D signal may be 1 (e.g., D may rise or go high). This may turn on FET 301 and turn off FET 302. In addition, FET 313 is turned off, FET 321 is turned on, FET 323 is turned off, FET 331 is turned on, FET 343 is turned on, and FET 341 is turned on. This allows signals to flow through FETS 304, 341, and 343. Also, FETS 361 and 363 are turned on and FET 306 is turned off because signal dclk is 1 when signal D is 1 and signal CPN is 0. FETS 373 and 383 are off, FET 391 is off, and FET 393 is on. FET 307 is also turned on which allows the D signal (e.g., 1 or logical high) to go to the output Q (at a second stage).

In some examples, the latch portion 350A and the bypass portion 350B operate simultaneously and may be used for both low voltage domain to high voltage domain level shifts and high voltage domain to low voltage domain level shifts. In some examples, the bypass portion 350B is faster than the latch portion 350A, and the latch portion attempts to catch-up before the CPN signal becomes 1 (and the latch becomes opaque). In some examples, the bypass portion 350B performs level shifting but not latching, and the level shifting latch circuit 300 relies on the latch portion 350A to performing latching and store the input value. In some examples, the latch portion 350A performs latching to provide hold protection and hold the input signal for a period of time (e.g., a half cycle) to help prevent data corruption. This may be helpful when transferring data from a higher voltage domain (such as memory in a high voltage state) to a lower voltage domain (such as a CPU in a low voltage state).

In some examples, level shifting latch circuit 300 includes a first circuit (e.g., latch portion 350A) configured to receive an input signal (e.g., input signal D) from a first voltage domain (e.g., voltage domain VDDI) and perform level shifting and latching functions on the input signal. In some examples, the level shifting latch circuit further includes a second circuit (e.g., bypass portion 350B) coupled to the first circuit and configured to receive the input signal from the first voltage domain at an input (e.g., gate of FET 361) of the second circuit, perform level shifting on the input signal, and provide a level-shifted signal for a second voltage domain (e.g., VDDO) at an output (e.g., output node Q) of the second circuit. The first circuit and the second circuit may operate concurrently on the input signal. The latching performed by the first circuit may provide hold protection for the input signal.

In some examples, the second circuit of the level shifting latch circuit 300 is configured to provide the level-shifted signal to the output in two stages. When the input signal is a falling signal, a first stage of the two stages may include inverting the input signal to generate an inverted signal (e.g., signal D going through an inverter to generate signal dbar, as shown in FIG. 3), and a second stage of the two stages may include turning on a first transistor (e.g., FET 391) coupled to the output, with the inverted signal to cause a level-shifted falling signal to be transferred to the output. When the input signal is a rising signal, a first stage of the two stages may include turning on a second transistor (e.g., FET 361), coupled to a gate of a third transistor (e.g., FET 307) that is coupled to the output, with the input signal, and a second stage of the two stages may include turning on the third transistor to cause a level-shifted rising signal to be transferred to the output.

In some examples, level shifting latch circuit 300 includes a latch portion 350A comprising a cross-coupled field-effect transistor (FET) structure for level shifting an input signal from a first domain to a second domain and a second FET structure for latching the input signal. Level shifting latch circuit 300 also includes a bypass portion 350B comprising a first set of two stages for level shifting and outputting the input signal when the input signal is a falling signal, and a second set of two stages for level shifting and outputting the input signal when the input signal is a rising signal.

In some examples, the cross-coupled FET structure includes a first FET (e.g., FET 301) and a second FET (e.g., FET 303) coupled in series between a power supply node (e.g., VDDO) and a second node (e.g., node ccnb below FET 303); and a third FET (e.g., FET 302) and a fourth FET (e.g., FET 304) coupled in series between the power supply node and a third node (e.g., the node ccn below FET 304), wherein a gate of the first FET and the fourth FET are coupled together and coupled to the third node, and wherein a gate of the second FET and the third FET are coupled together and coupled to the second node.

In some examples, the second FET structure comprises a fifth FET (e.g., FET 311) and a sixth FET (e.g., FET 313) coupled in series between the second node and ground, and a seventh FET (e.g., FET 351) and an eighth FET (e.g., FET 353) coupled in series between the third node and ground. In some examples, the bypass portion 350B is coupled to the latch portion 350A at a node between the third FET and the fourth FET.

In some examples of the level shifting latch circuit, a first stage of the first set of two stages includes an inverter (e.g., inverter converting signal D to signal dbar shown in FIG. 3) for inverting the falling signal to generate an inverted signal, and wherein a second stage of the first set of two stages includes a first FET (e.g., FET 391) coupled an output of the bypass portion, wherein the first FET is turned on with the inverted signal to cause a level-shifted falling signal to be transferred to the output.

In some examples of the level shifting latch circuit, a first stage of the second set of two stages includes a second FET (e.g., FET 361) that is turned on with the input signal, wherein a second stage of the second set of two stages includes a third FET (e.g., FET 307), wherein the second FET is coupled to a gate of the third FET, wherein the third FET is coupled to an output of the bypass portion, and wherein turning on the third FET with the second FET causes a level-shifted rising signal to be transferred to the output.

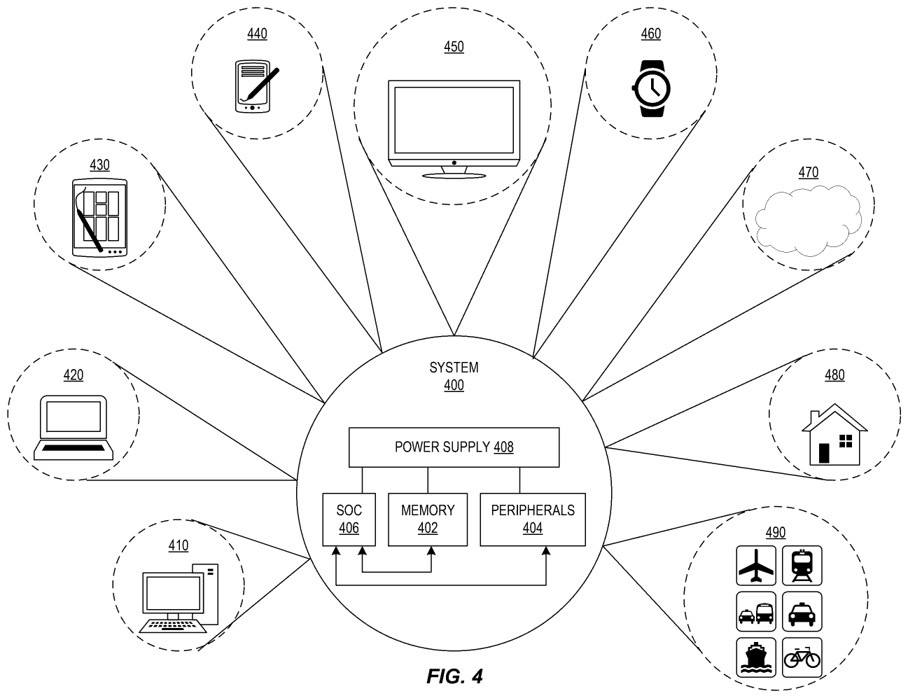

FIG. 4 illustrates a block diagram of an example system 400, in accordance with one or more embodiments of the present disclosure. The system 400 may incorporate and/or otherwise utilize the circuits, devices, components, methods, functions, and/or mechanisms described herein, including level shifting latch circuit 300 (FIG. 3). In the illustrated embodiment, the system 400 includes at least one instance of a system on chip (SoC) 406 which may include multiple types of processing units, such as a central processing unit (CPU), a graphics processing unit (GPU), or otherwise, a communication fabric, and interfaces to memories and input/output devices. In some embodiments, one or more processors in SoC 406 includes multiple execution lanes and an instruction issue queue. In various embodiments, SoC 406 is coupled to external memory 402, peripherals 404, and power supply 408. The system 400 may use plates (with regions and/or vias) that are coupled to various components (e.g., coupled to SoC 406).

A power supply 408 is also provided which supplies the supply voltages to SoC 406 as well as one or more supply voltages to the memory 402 and/or the peripherals 404. In various embodiments, power supply 408 represents a battery (e.g., a rechargeable battery in a smart phone, laptop or tablet computer, or other device). In some embodiments, more than one instance of SoC 406 is included (and more than one external memory 402 is included as well).

The memory 402 is any type of memory, such as dynamic random access memory (DRAM), synchronous DRAM (SDRAM), double data rate (DDR, DDR2, DDR3, etc.) SDRAM (including mobile versions of the SDRAMs such as mDDR3, etc., and/or low power versions of the SDRAMs such as LPDDR2, etc.), RAMBUS DRAM (RDRAM), static RAM (SRAM), etc. One or more memory devices are coupled onto a circuit board to form memory modules such as single inline memory modules (SIMMs), dual inline memory modules (DIMMs), etc. Alternatively, the devices are mounted with a SoC or an integrated circuit in a chip-on-chip configuration, a package-on-package configuration, or a multi-chip module configuration.

The peripherals 404 include any desired circuitry, depending on the type of system 400. For example, in one embodiment, peripherals 404 includes devices for various types of wireless communication, such as Wi-Fi, Bluetooth, cellular, global positioning system, etc. In some embodiments, the peripherals 404 also include additional storage, including RAM storage, solid state storage, or disk storage. The peripherals 404 include user interface devices such as a display screen, including touch display screens or multitouch display screens, keyboard or other input devices, microphones, speakers, etc.

As illustrated, system 400 is shown to have application in a wide range of areas. For example, system 400 may be utilized as part of the chips, circuitry, components, etc., of a desktop computer 410, laptop computer 420, tablet computer 430, cellular or mobile phone 440, or television 450 (or set-top box coupled to a television). Also illustrated is a smartwatch and health monitoring device 460. In some embodiments, the smartwatch may include a variety of general-purpose computing related functions. For example, the smartwatch may provide access to email, cellphone service, a user calendar, and so on. In various embodiments, a health monitoring device may be a dedicated medical device or otherwise include dedicated health related functionality. For example, a health monitoring device may monitor a user's vital signs, track proximity of a user to other users for the purpose of epidemiological social distancing, contact tracing, provide communication to an emergency service in the event of a health crisis, and so on. In various embodiments, the above-mentioned smartwatch may or may not include some or any health monitoring related functions. Other wearable devices are contemplated as well, such as devices worn around the neck, devices that are implantable in the human body, glasses designed to provide an augmented and/or virtual reality experience, and so on.

System 400 may further be used as part of a cloud-based service(s) 470. For example, the previously mentioned devices, and/or other devices, may access computing resources in the cloud (i.e., remotely located hardware and/or software resources). Still further, system 400 may be utilized in one or more devices of a home other than those previously mentioned. For example, appliances within the home 480 may monitor and detect conditions that warrant attention. For example, various devices within the home (e.g., a refrigerator, a cooling system, etc.) may monitor the status of the device and provide an alert to the homeowner (or, for example, a repair facility) should a particular event be detected. Alternatively, a thermostat may monitor the temperature in the home and may automate adjustments to a heating/cooling system based on a history of responses to various conditions by the homeowner. Also illustrated in FIG. 4 is the application of system 400 to various modes of transportation 490. For example, system 400 may be used in the control and/or entertainment systems of aircraft, trains, buses, cars for hire, private automobiles, waterborne vessels from private boats to cruise liners, scooters (for rent or owned), and so on. In various cases, system 400 may be used to provide automated guidance (e.g., self-driving vehicles), general systems control, and otherwise. These and many other embodiments are possible and are contemplated. It is noted that the devices and applications illustrated in FIG. 4 are illustrative only and are not intended to be limiting. Other devices are possible and are contemplated.

The present disclosure includes references to “an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent claims that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more. ” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there be at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third” when applied to a feature do not imply any type of ordering (e.g., spatial, temporal, logical, etc.), unless stated otherwise.

The phrase “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some tasks even if the structure is not currently being operated. Thus, an entity described or recited as being “configured to” perform some tasks refers to something physical, such as a device, circuit, a system having a processor unit and a memory storing program instructions executable to implement the task, etc. This phrase is not used herein to refer to something intangible.

In some cases, various units/circuits/components may be described herein as performing a set of tasks or operations. It is understood that those entities are “configured to” perform those tasks/operations, even if not specifically noted.

The term “configured to” is not intended to mean “configurable to. ” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

Various units, circuits, or other components may be described as “configured to” perform a task or tasks. In such contexts, “configured to” is a broad recitation of structure generally meaning “having circuitry that” performs the task or tasks during operation. As such, the unit/circuit/component can be configured to perform the task even when the unit/circuit/component is not currently on. In general, the circuitry that forms the structure corresponding to “configured to” may include hardware circuits. Similarly, various units/circuits/components may be described as performing a task or tasks, for convenience in the description. Such descriptions should be interpreted as including the phrase “configured to. ” Reciting a unit/circuit/component that is configured to perform one or more tasks is expressly intended not to invoke 35 U.S.C. § 112, paragraph (f) interpretation for that unit/circuit/component. More generally, the recitation of any element is expressly intended not to invoke 35 U.S.C. § 112, paragraph (f) interpretation for that element unless the language “means for” or “step for” is specifically recited. Should Applicant wish to invoke Section 112(f) during prosecution of a United States patent application based on this disclosure, it will recite claim elements using the “means for” [performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), functional unit, memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements may be defined by the functions or operations that they are configured to implement. The arrangement and such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used to transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits or portions thereof may also be custom-designed in a schematic editor and captured into the integrated circuit design along with synthesized circuitry. The integrated circuits may include transistors and other circuit elements (e.g., passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

Numerous variations and modifications will become apparent to those skilled in the art once the above disclosure is fully appreciated. It is intended that the following claims be interpreted to embrace all such variations and modifications.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. An apparatus, comprising:
a first circuit configured to receive an input signal from a first voltage domain and perform a first level shifting function and a latching function on the input signal; and
a second circuit coupled to the first circuit and configured to receive the input signal from the first voltage domain at an input of the second circuit, perform a second level shifting on the input signal, and provide a level-shifted signal for a second voltage domain at an output of the second circuit.

2. The apparatus of claim 1, wherein the first circuit and the second circuit operate concurrently on the input signal.

3. The apparatus of claim 1, wherein the latching function performed by the first circuit provides hold protection for the input signal.

4. The apparatus of claim 1, wherein the second circuit is configured to provide the level-shifted signal to the output in two stages.

5. The apparatus of claim 4, wherein the input signal is a falling signal, wherein a first stage of the two stages includes inverting the input signal to generate an inverted signal, and wherein a second stage of the two stages includes turning on a first transistor, coupled to the output, with the inverted signal to cause a level-shifted falling signal to be transferred to the output.

6. The apparatus of claim 4, wherein the input signal is a rising signal, wherein a first stage of the two stages includes turning on a second transistor, coupled to a gate of a third transistor that is coupled to the output, with the input signal, and wherein a second stage of the two stages includes turning on the third transistor to cause a level-shifted rising signal to be transferred to the output.

7. The apparatus of claim 1, wherein:
the first level shifting function shifts the input signal from the first voltage domain to the second voltage domain; and
the second level shifting function shifts the input signal from the first voltage domain to the second voltage domain.

8. A level shifting latch circuit, comprising:
a latch portion comprising a cross-coupled field-effect transistor (FET) structure for level shifting an input signal from a first domain to a second domain and a second FET structure for latching the input signal; and
a bypass portion comprising a first set of two stages for level shifting and outputting the input signal when the input signal is a falling signal, and a second set of two stages for level shifting and outputting the input signal when the input signal is a rising signal.

9. The level shifting latch circuit of claim 8, wherein the cross-coupled FET structure comprises:
a first FET and a second FET coupled in series between a power supply node and a second node; and
a third FET and a fourth FET coupled in series between the power supply node and a third node, wherein a gate of the first FET and the fourth FET are coupled together and coupled to the third node, and wherein a gate of the second FET and the third FET are coupled together and coupled to the second node.

10. The level shifting latch circuit of claim 9, wherein the first FET, the second FET, the third FET, and the fourth FET are each a p-channel metal-oxide-semiconductor field-effect transistor (PMOS FET).

11. The level shifting latch circuit of claim 9, wherein the second FET structure comprises a fifth FET and a sixth FET coupled in series between the second node and ground, and a seventh FET and an eighth FET coupled in series between the third node and ground.

12. The level shifting latch circuit of claim 11, wherein the fifth FET, the sixth FET, the seventh FET, and the eighth FET are each an n-channel metal-oxide-semiconductor field-effect transistor (NMOS FET).

13. The level shifting latch circuit of claim 9, wherein the bypass portion is coupled to the latch portion at a node between the third FET and the fourth FET.

14. The level shifting latch circuit of claim 8, wherein a first stage of the first set of two stages includes an inverter for inverting the falling signal to generate an inverted signal, and wherein a second stage of the first set of two stages includes a first FET coupled an output of the bypass portion, wherein the first FET is turned on with the inverted signal to cause a level-shifted falling signal to be transferred to the output.

15. The level shifting latch circuit of claim 8, wherein a first stage of the second set of two stages includes a second FET that is turned on with the input signal, wherein a second stage of the second set of two stages includes a third FET, wherein the second FET is coupled to a gate of the third FET, wherein the third FET is coupled to an output of the bypass portion, and wherein turning on the third FET with the second FET causes a level-shifted rising signal to be transferred to the output.

16. The level shifting latch circuit of claim 15, wherein the second FET is an n-channel metal-oxide-semiconductor field-effect transistor (NMOS FET), and wherein the third FET is a p-channel metal-oxide-semiconductor field-effect transistor (PMOS FET).

17. A method, comprising:
receiving, by a first circuit from a first voltage domain, an input signal;
performing, by the first circuit, a first level shifting function and a latching function on the input signal;
receiving, by a second circuit coupled to the first circuit, the input signal from the first voltage domain at an input of the second circuit;
performing, by the second circuit, a second level shifting function on the input signal; and
providing, by the second circuit, a level-shifted signal for a second voltage domain at an output of the second circuit.

18. The method of claim 17, wherein the first circuit and the second circuit operate concurrently on the input signal.

19. The method of claim 17, wherein the latching performed by the first circuit provides hold protection for the input signal.

20. The method of claim 17, wherein the second circuit is configured to provide the level-shifted signal to the output in two stages.
